(19) United States
(12) Patent Application Publication
(10) Pub. No.: US 2026/0196983 A1
(43) Pub. Date: Jul. 9, 2026

(54) ACOUSTIC SCATTERING STRUCTURE

(71) Applicant: SKYWORKS SOLUTIONS, INC., Irvine, CA (US)

(72) Inventors: Cedric Olivier Gerald Poirel, Irvine, CA (US); Joshua James Caron, Summerfield, NC (US)

(21) Appl. No.: 19/440,992

(22) Filed: Jan. 6, 2026

Related U.S. Application Data
(60) Provisional application No. 63/743,426, filed on Jan. 9, 2025.

(51) Int. Cl. H03H 9/64; H03H 9/25; H03H 9/72

(52) U.S. Cl. CPC H03H 9/6483; H03H 9/25; H03H 9/725

(57) ABSTRACT

Aspects and embodiments disclosed herein include a die comprising a first surface acoustic wave (SAW) resonator disposed on a surface of a substrate, a second SAW resonator disposed on the surface of the substrate, and an acoustic scattering structure disposed between the first SAW resonator and the second SAW resonator, the acoustic scattering structure including one or more trenches formed in the surface of the substrate.

### CROSS-REFERENCE TO RELATED APPLICATIONS

This application claims priority under 35 U.S.C. § 119(e) to U.S. Provisional Patent Application Ser. No. 63/743,426, titled “ACOUSTIC SCATTERING STRUCTURE”, filed Jan. 9, 2025, the entire content of which is incorporated herein by reference for all purposes.

### BACKGROUND

### Field

Aspects and embodiments disclosed herein relate to an acoustic wave device and a radio frequency filter and electronic module including the same. In particular, aspects and embodiments disclosed herein relate to surface acoustic wave devices including acoustic scattering structures.

### Description of the Related Technology

Acoustic wave devices, for example, surface acoustic wave (SAW) devices may be utilized as components of filters in radio frequency electronic systems. For instance, filters in a radio frequency front end of a mobile phone can include acoustic wave filters. Two acoustic wave filters can be arranged as a duplexer.

### SUMMARY

According to one embodiment there is provided a die comprising a first surface acoustic wave (SAW) resonator disposed on a surface of a substrate, a second SAW resonator disposed on the surface of the substrate, and an acoustic scattering structure disposed between the first SAW resonator and the second SAW resonator, the acoustic scattering structure including one or more trenches formed in the surface of the substrate.

In some embodiments, the one or more trenches have lengths and widths, the lengths of the one or more trenches being greater than the widths of the one or more trenches, the lengths of the one or more trenches extending in a direction normal to a direction of propagation of main acoustic waves through one or both of the first SAW resonator and the second SAW resonator.

In some embodiments, the one or more trenches include a first trench having a first length and a second trench having a second length different from the first length.

In some embodiments, the one or more trenches include a first trench having a first width and a second trench having a second width different from the first width.

In some embodiments, the one or more trenches include a first trench and a second trench, the first trench displaced from the second trench in the direction of propagation of the main acoustic waves through the one or both of the first SAW resonator and the second SAW resonator.

In some embodiments, the one or more trenches include a first trench and a second trench, the first trench displaced from the second trench in the direction normal to the direction of propagation of the main acoustic waves through the one or both of the first SAW resonator and the second SAW resonator.

In some embodiments, the one or more trenches each includes at least one linear section disposed at an angle relative to the direction normal to the direction of propagation of the main acoustic waves through the one or both of the first SAW resonator and the second SAW resonator in a plane defined by the surface of the substrate.

In some embodiments, the one or more trenches each includes multiple connected linear sections, at least one of the multiple connected linear sections disposed at an angle relative to at least one other of the multiple connected linear sections in the plane defined by the surface of the substrate.

In some embodiments, the one or more trenches each includes at least one curved section.

In some embodiments, the one or more trenches each includes multiple connected curved sections, at least one of the multiple connected curved sections having a different curvature than at least one other of the multiple connected curved sections.

In some embodiments, the substrate is a multilayer piezoelectric substrate including a layer of piezoelectric material having an upper surface upon which interdigital transducer electrodes of the first SAW resonator and the second SAW resonator are disposed.

In some embodiments, at least one of the first SAW resonator or the second SAW resonator includes a pair of interdigital transducer electrodes disposed on an upper surface of the layer of piezoelectric material, each interdigital transducer electrode including a bus bar and a plurality of electrode fingers extending from the bus bar towards an edge region of the interdigital transducer electrode at distal ends of the electrode fingers, and trench portions located in the upper surface of the layer of piezoelectric material, the trench portions overlapping with the edge regions of the interdigital transducer electrodes.

In some embodiments, the trench portions of the at least one of the first SAW resonator or the second SAW resonator and the one or more trenches of the acoustic scattering structure have same depths.

In some embodiments, the trench portions of the at least one of the first SAW resonator or the second SAW resonator and the one or more trenches of the acoustic scattering structure have same widths.

In accordance with another aspect, there is provided a radio frequency filter comprising interdigital transducer electrodes of a first surface acoustic wave (SAW) resonator disposed on a surface of a substrate, interdigital transducer electrodes of a second SAW resonator disposed on the surface of the substrate, and an acoustic scattering structure disposed between the interdigital transducer electrodes of the first SAW resonator and the interdigital transducer electrodes of the second SAW resonator, the acoustic scattering structure including one or more trenches formed in the surface of the substrate.

In some embodiments, the radio frequency filter is included in a duplexer.

In some embodiments, the duplexer comprises a loop cancellation circuit including at least one of the first SAW resonator or the second SAW resonator, the at least one of the first SAW resonator or the second SAW resonator lacking reflector electrodes.

In accordance with another aspect, there is provided an electronics module comprising at least one radio frequency filter that includes interdigital transducer electrodes of a first surface acoustic wave (SAW) resonator disposed on a surface of a substrate, interdigital transducer electrodes of a second SAW resonator disposed on the surface of the substrate, and an acoustic scattering structure disposed between the interdigital transducer electrodes of the first SAW resonator and the interdigital transducer electrodes of the second SAW resonator, the acoustic scattering structure including one or more trenches formed in the surface of the substrate.

In some embodiments, he one or more trenches each includes multiple connected linear sections, at least one of the multiple connected linear sections disposed at an angle relative to at least one other of the multiple connected linear sections in the plane defined by the surface of the substrate.

In some embodiments, the one or more trenches each includes multiple connected curved sections.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the disclosed aspects and embodiments. In the figures, each identical or nearly identical component that is illustrated in various figures is represented by a like numeral. For purposes of clarity, not every component may be labeled in every figure. In the figures:

FIG. 1A is a simplified plan view of an example of a surface acoustic wave resonator;

FIG. 1B is a simplified plan view of another example of a surface acoustic wave resonator;

FIG. 1C is a simplified plan view of another example of a surface acoustic wave resonator;

FIG. 2 is a cross-sectional view of a portion of a surface acoustic wave resonator having an example of a multilayer piezoelectric substrate;

FIG. 3 is a cross-sectional view of a portion of a surface acoustic wave resonator having another example of a multilayer piezoelectric substrate;

FIG. 4A is a plan view of a portion of an acoustic wave device including a trench in a piezoelectric material layer;

FIG. 4B shows a cross-section through the line in FIG. 4A labeled A;

FIG. 4C shows a cross-section through the line in FIG. 4A labeled B;

FIG. 4D shows a partial cross-section through the line in FIG. 4A labeled C;

FIG. 4E shows a partial cross-section through the line in FIG. 4A labeled D;

FIG. 5 illustrates an example of a die including multiple acoustic wave resonators;

FIG. 6 illustrates an example of a duplexer including a loop cancellation circuit;

FIG. 7 illustrates an example of a die including multiple surface acoustic wave resonators and examples of acoustic scattering structures;

FIG. 8 illustrates an example of a die including multiple surface acoustic waver resonators and other examples of acoustic scattering structures;

FIG. 9 is a block diagram of one example of a filter module that can include one or more acoustic wave devices according to aspects disclosed herein;

FIG. 10 is a block diagram of one example of a front-end module that can include one or more filter modules including acoustic wave devices according to aspects disclosed herein; and

FIG. 11 is a block diagram of one example of a wireless device including the front-end module of FIG. 10.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Aspects and embodiments of the present disclosure are described below through embodiments of acoustic wave devices, in particular surface acoustic wave (SAW) devices. However, as would be understood by the skilled person, various different excitation modes are possible in acoustic wave filters and devices, particularly multilayer piezoelectric substrate (MPS) devices. As well as surface acoustic waves other types of acoustic wave are possible such as boundary acoustic waves and guided acoustic waves. References to surface acoustic waves and SAW devices in the following description are not intended to limit the disclosure from including or covering other possible types of acoustic waves and acoustic wave devices.

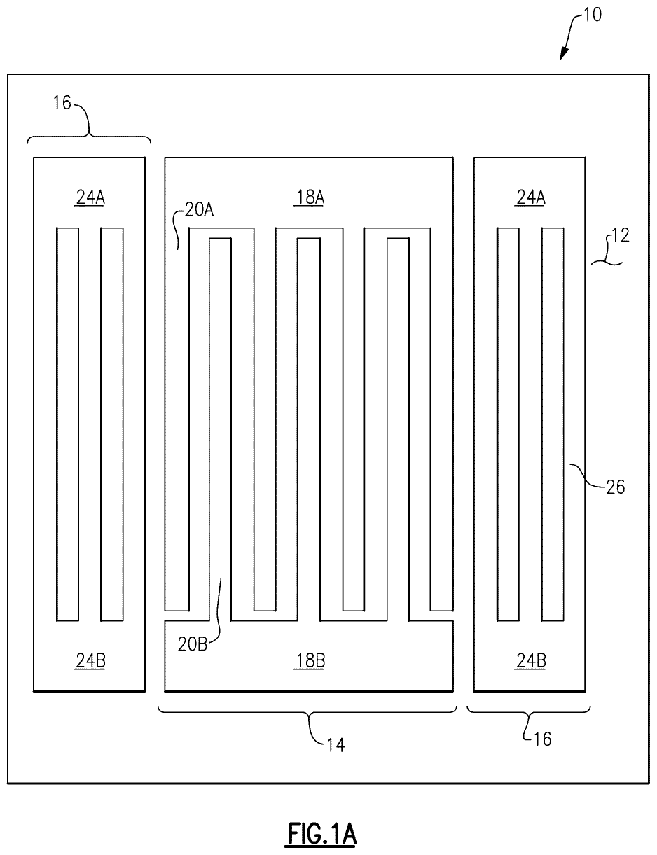

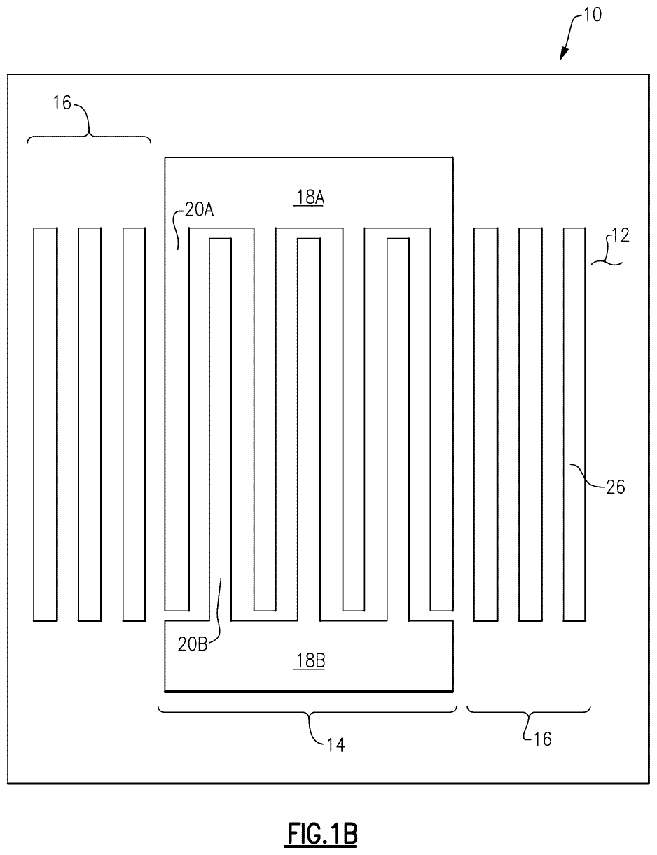

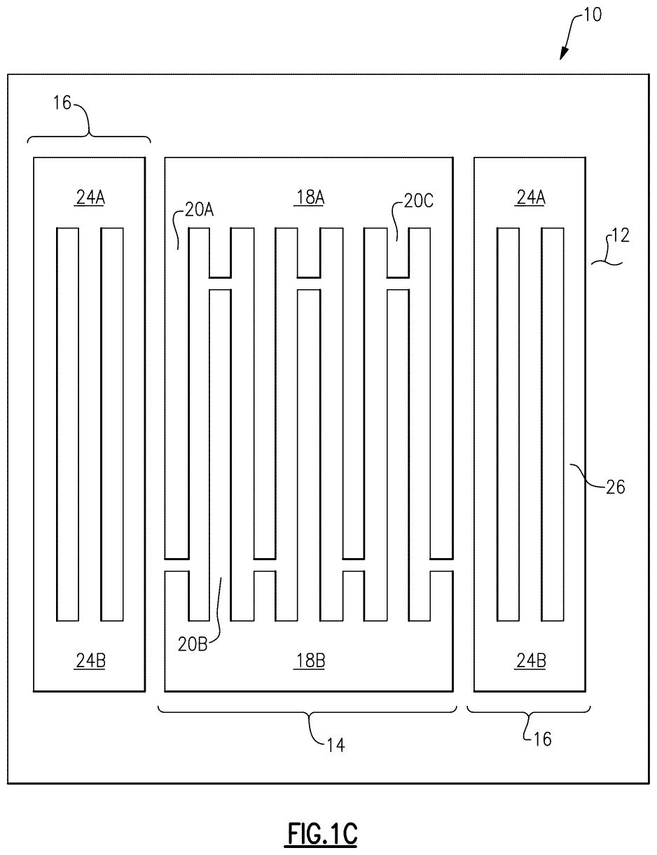

FIG. 1A is a plan view of a SAW resonator 10 such as might be used in a SAW filter, duplexer, balun, etc.

Acoustic wave resonator 10 is formed on a piezoelectric substrate, for example, a lithium tantalate (LiTaO₃) or lithium niobate (LiNbO₃) substrate 12 and includes Interdigital Transducer (IDT) electrodes 14 and reflector electrodes 16. In use, the IDT electrodes 14 excite a main acoustic wave having a wavelength λ along a surface of the piezoelectric substrate 12. The reflector electrodes 16 sandwich the IDT electrodes 14 and reflect the main acoustic wave back and forth through the IDT electrodes 14. The main acoustic wave of the device travels perpendicular to the lengthwise extension direction of the IDT electrodes.

The IDT electrodes 14 include a first bus bar electrode 18A and a second bus bar electrode 18B facing first bus bar electrode 18A. The IDT electrodes 14 further include first electrode fingers 20A extending from the first bus bar electrode 18A toward the second bus bar electrode 18B, and second electrode fingers 20B extending from the second bus bar electrode 18B toward the first bus bar electrode 18A.

The reflector electrodes 16 (also referred to as reflector gratings) each includes a first reflector bus bar electrode 24A and a second reflector bus bar electrode 24B (collectively referred to herein as reflector bus bar electrode 24) and reflector fingers 26 extending between and electrically coupling the first bus bar electrode 24A and the second bus bar electrode 24B.

In other embodiments disclosed herein, as illustrated in FIG. 1B, the reflector bus bar electrodes 24 may be omitted and the reflector fingers 26 may be electrically unconnected. Further, as illustrated in FIG. 1C, acoustic wave resonators as disclosed herein may include dummy electrode fingers 20C that are aligned with respective electrode fingers 20A, 20B. Each dummy electrode finger 20C extends from the opposite bus bar electrode 18A, 18B than the respective electrode finger 20A, 20B with which it is aligned.

It should be appreciated that the acoustic wave resonators 10 illustrated in FIGS. 1A-1C, as well as the other circuit elements illustrated in other figures presented herein, are illustrated in a highly simplified form. The relative dimensions of the different features are not shown to scale. Further, typical acoustic wave resonators would commonly include a far greater number of IDT electrode fingers and reflector electrode fingers than illustrated. Typical acoustic wave resonators or filter elements may also include multiple IDT electrodes sandwiched between the reflector electrodes.

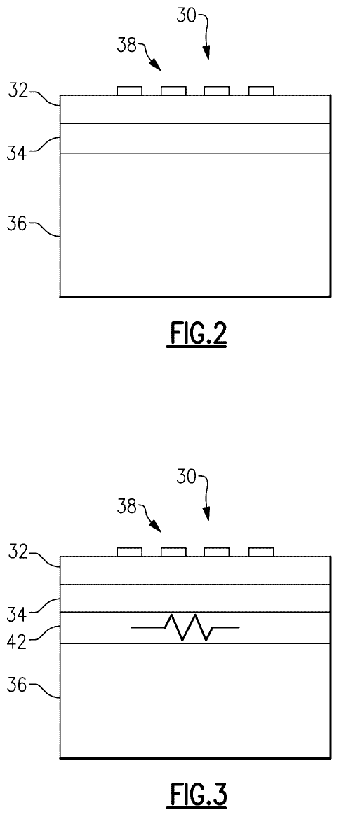

FIG. 2 is a partial cross-sectional view of an acoustic wave resonator 30 having a multilayer piezoelectric substrate including a layer 32 of piezoelectric material, for example, lithium tantalate or lithium niobate, a dielectric material layer 34, for example, silicon dioxide, on which the layer 32 of piezoelectric material is disposed, and a carrier substrate 36 on which the dielectric material layer 34 is disposed. IDT and reflector electrodes, indicated collectively at 38, having configurations such as illustrated in any of FIGS. 1A-1C may be disposed on the upper surface of the layer 32 of piezoelectric material. The carrier substrate 36 may be formed of, for example, Si. Advantages of forming an acoustic wave resonator 30 with a multiplayer piezoelectric substrate as illustrated in FIG. 2 is that the Si material for the carrier substrate 36 is widely available and easily processed by techniques developed in the semiconductor industry. A disadvantage of forming an acoustic wave resonator 30 with a multiplayer piezoelectric substrate as illustrated in FIG. 2 is that an interface between the upper surface of the Si carrier substrate 36 and the lower surface of the dielectric material layer 34 may include parasitic surface charges that may cause the resonator to exhibit a lower quality factor Q than desirable due to losses caused by parasitic surface conductivity associated with the parasitic surface charges. This undesirable effect may be at least partially alleviated by forming a trap-rich layer 42, for example, a layer of polysilicon in the upper portion of the Si carrier substrate 36 as illustrated in FIG. 3.

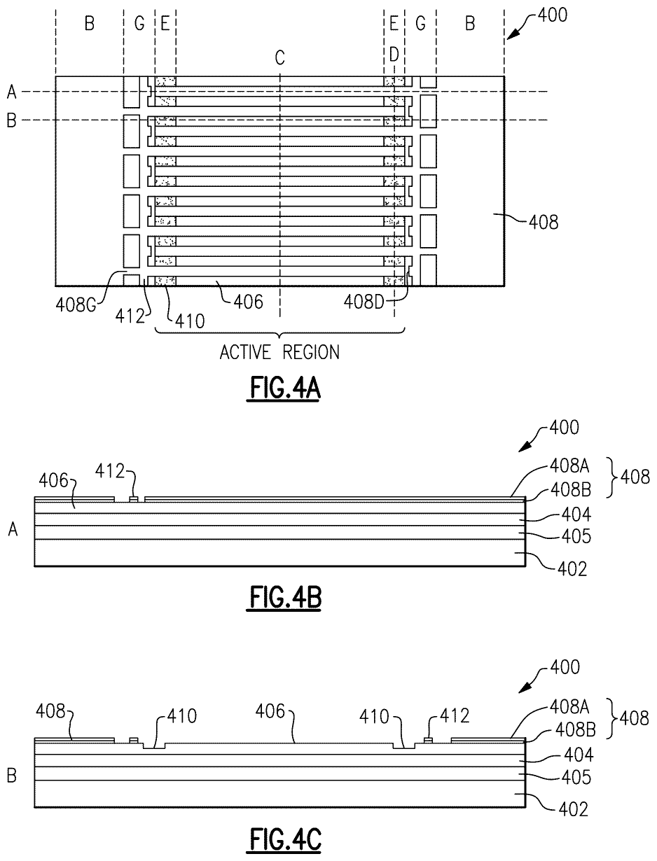

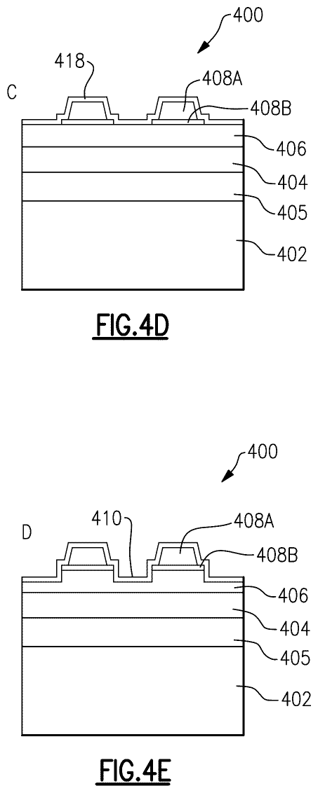

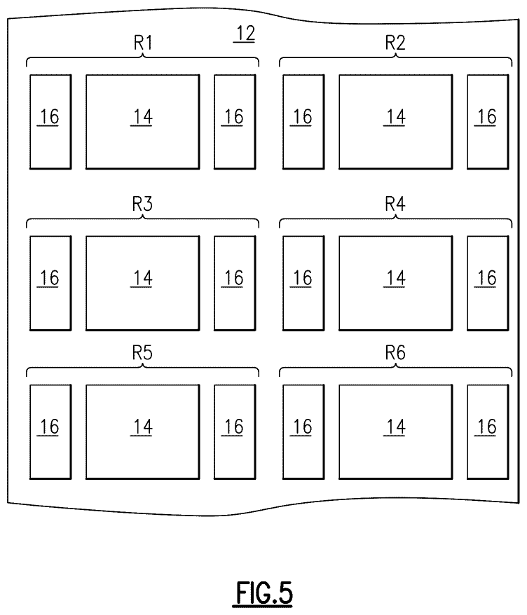

FIG. 4A is a plan view of a portion of a SAW device including multilayer piezoelectric substrate and a piezoelectric material layer trench structure. Reflector electrodes are omitted from FIG. 4A for the purpose of clarity, but it is to be understood that the SAW device of FIG. 4A may include reflector electrodes similar to those shown in, for example, any of FIGS. 1A-1C. FIGS. 4B and 4C show cross-sections through the lines in FIG. 4A labeled A and B respectively. FIGS. 4D and 4E show partial cross-sections through the lines in FIG. 4A labeled C and D respectively (with only two IDT fingers shown in FIGS. 4D and 4E for clarity).

The acoustic wave device 400 includes a carrier substrate 402, a layer of dielectric material 404 disposed above the upper surface of the carrier substrate 402, and a layer of piezoelectric material 406 disposed above the layer of dielectric material 404. The acoustic wave device 400 further includes an additional layer 405 disposed between the carrier substrate 402 and the layer of dielectric material 404. The additional layer 405 may include or consist of, for example, aluminum nitride, silicon nitride, polysilicon, or amorphous silicon. The additional layer 405 may be a trap-rich layer that helps improve the quality factor Q of the acoustic wave device by reducing the effects of parasitic surface conductivity on the upper surface of the carrier substrate 402.

Any piezoelectric material may be used as the layer of piezoelectric material 406, for example, including but not limited to lithium tantalate (LiTaO₃), aluminum nitride (AlN), lithium niobate (LiNbO₃), or potassium niobate (KNbO₃). Various materials may also be used in the layer of dielectric material 404 and in the carrier substrate 402. One example of a material that may be utilized for the layer of dielectric material 404 is silicon dioxide (SiO₂). Other examples may include doped materials such as F doped SiO₂, or Ti doped SiO₂. One example of a material that may be utilized for the carrier substrate 402 is silicon (Si), however, aluminum nitride, silicon nitride, magnesium oxide spinel, magnesium oxide crystal, quartz, diamond, DLC (diamond-like carbon), and sapphire may all also or alternatively be used as the carrier substrate.

The carrier substrate 402 may be formed of a material having a lower coefficient of linear expansion and/or a higher thermal conductivity and/or a higher toughness or mechanical strength than the piezoelectric material 406. The carrier substrate 402 may both increase the mechanical robustness of the SAW device during fabrication and increase manufacturing yield, as well as reducing the amount by which operating parameters of the SAW device change with temperature during operation. The carrier substrate 402 may be referred to as a high impedance support substrate.

An interdigital transducer (IDT) 408 is disposed on top of the layer of piezoelectric material 406 and is configured to generate a surface acoustic wave in the multilayer piezoelectric substrate. In use, the IDT 408 excites a main acoustic wave having a wavelength λ along a surface of the multilayer piezoelectric substrate. The acoustic wave is concentrated in the top two layers (the layer of dielectric material 404 and layer of piezoelectric material 406). The carrier substrate 402 (silicon in this example) may have a high impedance meaning the acoustic wave is reflected from the upper surface of the carrier substrate 402, confining the surface acoustic wave in the upper layers. In some embodiments, the thickness of the layer of dielectric material 404 may be between 0.1λ and 1λ, for example, between 0.1λ and 0.5λ, and the thickness of the layer of piezoelectric material 406 may be between 0.1λ and 1λ, for example, between 0.1λ and 0.5λ. It is to be understood that the dimensions above are only examples and may be set at different values in different embodiments of acoustic wave devices to achieve different design goals.

Any type of IDT may be used as the IDT 408 in the acoustic wave device 400. For example, a typical IDT will include a pair of interlocking comb shaped IDT electrodes. Each electrode of the IDT typically includes a bus bar and a plurality of electrode fingers that extend perpendicularly from the bus bar. Typically, the distance between the central point of each adjacent electrode finger extending from the same bus bar is equal to the wavelength λ of the surface acoustic wave generated. The bus bars of each of the pair of IDT electrodes are parallel and opposing each other, and the plurality of electrode fingers of each IDT electrode extend towards to the bus bar of the opposing electrode, such that the electrode fingers interlock, typically with a distance of λ/2 between the centers of each set of adjacent electrode fingers extending from opposite bus bars. The main surface acoustic wave generated by the IDT travels perpendicular to the lengthwise extension direction of the IDT electrode fingers, and parallel to the lengthwise extension direction of the IDT bus bars.

Regardless of the type of IDT used, the IDT 408 has an active region defined as the region in which the fingers of each IDT electrode interleave with one another. The surface acoustic wave is generated in the active region of the IDT. The active region of the IDT includes a central region and two edge regions. The central region is labeled by the letter C in FIG. 4A and the edge regions are labeled by the letter E. Each edge region E extends from the tips of the plurality of fingers of one of the electrodes towards the center of the central region C. The edge regions E include end portions of the IDT electrode fingers, and the central region C is sandwiched between the edge regions. The purpose of the edge regions will be discussed in more detail below. The IDT also includes gap regions labeled with the letter G in FIG. 4A. The gap regions are located between the ends of the fingers of one of the IDT electrodes and the bus bar of the other IDT electrode. The regions containing the bus bars are labeled B in FIG. 4A. The dashed lines in FIG. 4A show the boundaries between the above described regions.

In the embodiment of FIG. 4A, the IDT electrodes 408 each includes a second bus bar 412 that is located within the gap region G. The second bus bars 412 extend parallel to the bus bars, and are located adjacent to the edge regions E of the IDT 408. The second bus bars 412 are thinner than the bus bars, and may be referred to as “mini bus bars”. The mini bus bars result in transverse vibrational modes being suppressed more effectively. However, in some embodiments these mini bus bars may be omitted.

The acoustic wave device 400 includes short dummy electrode fingers 408D extending from sides of the mini-busbars 412 facing the central region C through a portion of the gap region G toward tips of IDT electrode fingers extending from the opposite busbars. The short dummy electrode fingers 408D may have the same width and may be aligned with the IDT electrode fingers toward which they extend. The short dummy electrode fingers 408D may increase the quality factor Q of the acoustic wave device 400 by providing better confinement of the acoustic wave in the resonator while keeping transverse modes suppressed.

The acoustic wave device 400 also includes portions of the IDT electrode fingers 408G within the gap region G between the mini-busbars 412 and main busbars that are thinner than the remainder of the IDT electrode fingers in a direction of propagation of the main acoustic wave through the device. These thinner portions 408G of the IDT electrode fingers may also increase the quality factor Q of the acoustic wave device 400 by providing better confinement of the acoustic wave in the resonator. In other embodiments, the IDT electrode fingers may have the same width across their entire lengths.

In the embodiments of FIGS. 4A to 4E a double layer IDT 408 is used, with an upper IDT layer 408a and a lower IDT layer 408b. However, single layer IDTs may also be used. In general, various IDT structures are possible, as would be understood by the skilled person, for example double electrode IDTs, or IDTs with dummy electrode fingers may be used.

The acoustic wave device 400 further includes trench structures in the layer of piezoelectric material for suppressing the transverse modes. Trench portions 410 are located in the upper surface of the layer of piezoelectric material. The trench portions 410 overlap with the edge regions E of the IDT electrodes 408. The trench portions 410 are located within the active region of the IDT 408, in the edge regions E of the IDT 408, and form a boundary of the active region running parallel with the bus bars. The trench portions 410 slow down the acoustic velocity at the edges of the active region to create a piston mode acoustic wave distribution, and thus suppress the transverse modes.

As can be seen from FIG. 4A, the trench portions 410 extend parallel to the bus bars, in the direction of propagation of the main acoustic wave generated by the IDT 408. However, the trench portions are only present in the sections of the upper surface of the layer of piezoelectric material 406 that are overlapped by the edge regions E of the IDT 408 and are not covered by the material of the IDT 408. The trench portions 410 are only cut into the surface of the layer of piezoelectric material 406 that is exposed after the IDT 408 has been formed on the layer of piezoelectric material 406. The trench portions 410 are not cut into the sections of the layer of piezoelectric material 406 covered by the IDT 408, meaning the trench portions 410 do not run underneath the IDT 408. The layer of piezoelectric material 406 remains at full thickness underneath the IDT 408. This is best seen in FIG. 4E, showing the trench portions 410 cut into the upper surface of the layer of piezoelectric material 406 not covered by the IDT 408, and not cut into the upper surface of the layer of piezoelectric material 406 covered by the IDT 408. A comparison of the cross-sectional views of FIGS. 4B and 4C also shows this. Therefore, the trench portions 410 can be described as extending discontinuously in the direction of propagation of the main acoustic wave generated by the IDT 408.

The trench portions 410 can be formed in this way by etching the layer of piezoelectric material. In particular, the trenches portions 410 may be etched after the formation of the IDT 408 on the upper surface of the layer of piezoelectric material 406, with the IDT preventing etching of the layer of piezoelectric material 406 underneath the IDT.

In some embodiments, the trench portions may each have a width in a direction perpendicular to the direction of propagation of an acoustic wave to be generated by the IDT 408 of between about 0.5λ and 1λ, where λ is the wavelength of the main acoustic wave to be generated by the IDT 408. In some embodiments, the trench portions may each have a depth relative to the upper surface of the layer of piezoelectric material of between about 0.004λ and 0.02λ.

As best seen in FIG. 4E, due to the trench portions 410, the sections of the electrode fingers of the IDT 408 in the edge regions E (the tips of the electrode fingers) are positioned higher relative to the surface of the layer of piezoelectric material 406 at the bottom of the trench portions. Therefore, the trench portions 410 increase the effective thickness of the IDT electrodes 408 seen by the acoustic wave within the edge regions E. The increased effective thickness of the IDT 408 in the edge regions E results in the piston mode distribution, which suppresses the transverse modes.

Radio frequency acoustic wave devices such as filters or duplexers are often formed with multiple acoustic wave resonators disposed on a single multilayer piezoelectric substrate. FIG. 5 is a block diagram illustrating a portion of a filter or a duplexer including six surface acoustic wave resonators R1-R6 disposed on a multilayer piezoelectric substrate 12, each including IDT electrodes 14 and reflector electrodes 16. Electrical connections between the resonators are not shown so as not to obscure the diagram. The relative positions and sizes of the surface acoustic wave resonators R1-R6 are exemplary only and are not intended to be limiting. In some designs a subset of the resonators R1-R6 may have similar operating frequencies or passbands. The reflector electrodes 16 generally will not contain all acoustic energy within a respective resonator. The reflector electrodes 16 of one resonator may allow some energy in the form of acoustic waves to leak from that resonator to another one of the resonators, which may cause interference if the two resonators are operating at similar frequencies or passbands. In other designs a first subset of the resonators R1-R6 may have a different operating frequency or passband than a second (or third, or fourth, etc.) subset of the resonators R1-R6. Reflector electrodes 16 are typically tuned to reflect acoustic energy within a particular passband. If one of the resonators generates spurious acoustic wave signals at a frequency (or frequencies) outside a passband that its reflector electrodes are designed to reflect, these spurious signals may leak out of the resonator to another resonator where they may cause interference, especially if the spurious signals are at frequencies within the passband of the other resonator.

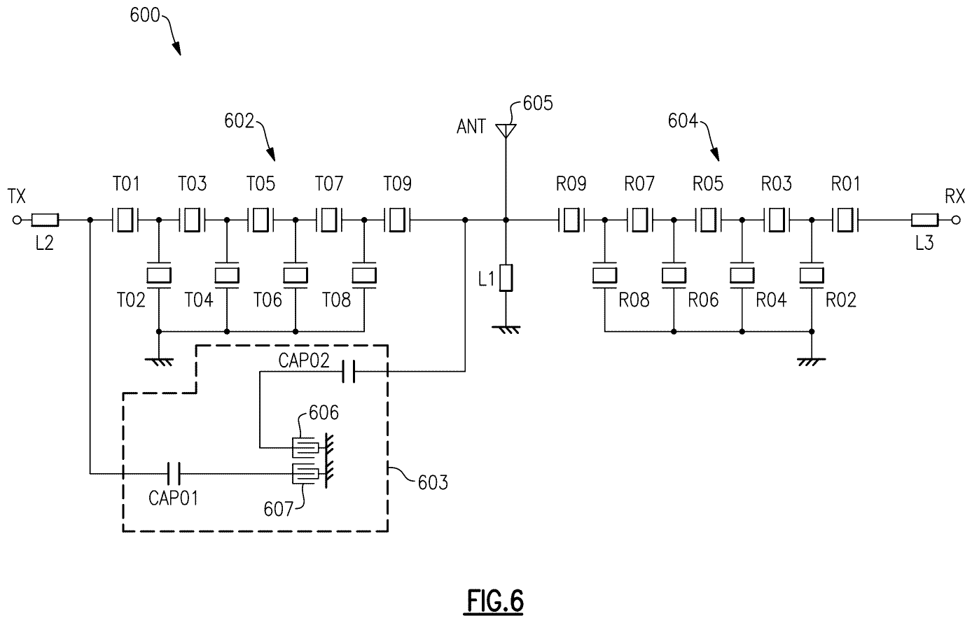

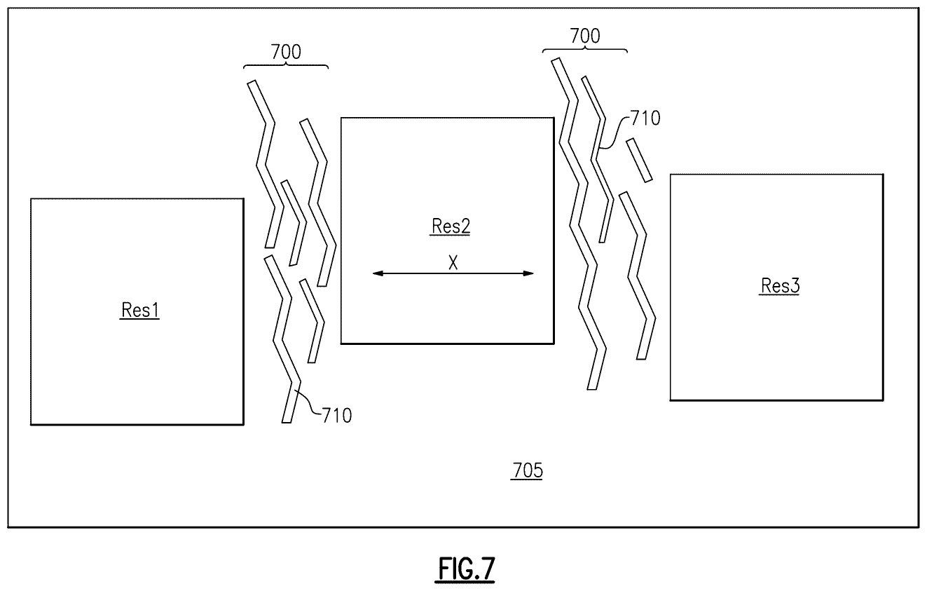

Some radio frequency surface acoustic wave devices may include surface acoustic wave resonators that do not have associated reflector electrodes. In one example, FIG. 6 illustrates a schematic diagram of a duplexer 600 with a loop circuit 603 for a transmit filter 602. The duplexer 600 includes a transmit filter 602, a receive filter 604, and a loop circuit 603. The transmit filter 602 and the receive filter 604 are coupled together at a node, which is an antenna node in FIG. 6. An antenna 605 is coupled to the antenna node of the duplexer 600. A shunt inductor L1 can be coupled between the antenna 605 and ground.

The transmit filter 602 can filter an RF signal received at the transmit port TX for transmission via the antenna 605. A series inductor L2 can be coupled between the transmit port TX and acoustic wave resonators of the transmit filter 602. The transmit filter 602 is an acoustic wave filter that includes acoustic wave resonators arranged as a ladder filter. The transmit filter 602 includes series resonators T01, T03, T05, T07, T09 and shunt resonators T02, T04, T06, T08. The transmit filter 602 can include any suitable number of series resonators and any suitable number of shunt resonators. The acoustic wave resonators of the transmit filter 602 can include bulk acoustic wave (BAW) resonators, such as film bulk acoustic wave resonators and/or solidly mounted resonators (SMRs). In some instances, the acoustic wave resonators of the transmit filter 602 can include SAW resonators or Lamb wave resonators. In certain examples, the resonators of the transmit filter 602 can include two or more types of resonators (e.g., one or more SAW resonators and one or more BAW resonators).

A loop circuit 603 is coupled to the transmit filter 602. The loop circuit 603 can be coupled to an input resonator T01 and an output resonator T09 of the transmit filter. In some other instances, the loop circuit 603 can be coupled to a different node of the ladder circuit than illustrated. The loop circuit 603 can apply a signal having approximately the same amplitude and an opposite phase to a signal component to be cancelled. The loop circuit 603 includes surface acoustic wave resonators 606 and 607 coupled to the transmit filter 602 by capacitors CAP02 and CAP01, respectively.

The receive filter 604 can filter a received RF signal received by the antenna 605 and provide a filtered RF signal to a receive port RX. The receive filter 604 is an acoustic wave filter that includes acoustic wave resonators arranged as a ladder filter. The receive filter 604 includes series resonators R01, R03, R05, R07, R09 and shunt resonators R02, R04, R06, R08. The receive filter 604 can include any suitable number of series resonators and any suitable number of shunt resonators. The acoustic wave resonators of the receive filter 604 can include BAW resonators, such as film bulk acoustic wave resonators and/or SMRs. In some instances, the acoustic wave resonators of the receive filter 604 can include SAW resonators or Lamb wave resonators. In certain examples, the resonators of the receive filter 604 can include two or more types of resonators (e.g., one or more SAW resonators and one or more BAW resonators). A series inductor L3 can be coupled between the acoustic wave resonators of the receive filter 604 and the receive port RX.

It is to be appreciated that in other embodiments, a loop cancellation circuit may be coupled to the receive filter 604 in addition to or as an alternative to the loop circuit 603 coupled to the transmit filter 602.

The signal generated by the loop circuit 603 is generally not required to have high quality factor (Q) because the loop circuit signal is utilized to cancel out of band signals in the transmit filter that typically have much lower amplitudes than signals within the passband of the transmit filter. Accordingly, reflector electrodes, which might otherwise confine acoustic energy within the loop circuit resonators 606, 607 and maintain a high Q of the signals generated by these resonators, may be omitted from the acoustic wave resonators 606 and 607 of the loop circuit to save space on the die on which they are formed. The lack of reflector electrodes in the acoustic wave resonators 606 and 607 of the loop circuit, however, may allow acoustic signals to leak from these acoustic wave resonators 606 and 607 to other resonators in the transmit filter or receive filter where they may cause interference with the operation of the other resonators.

Applicants have thus found it desirable to provide structures that may enhance the ability of reflector electrodes to prevent signal leakage from one surface acoustic wave resonator to another in an acoustic wave device or to make up for the lack of reflector electrodes in resonators such as resonators 606 and 607 of the duplexer of FIG. 6. Such structures may be configured to scatter acoustic waves that may leak out of one resonator and that might otherwise reach another resonator and possibly interfere with the proper functioning of the other resonator.

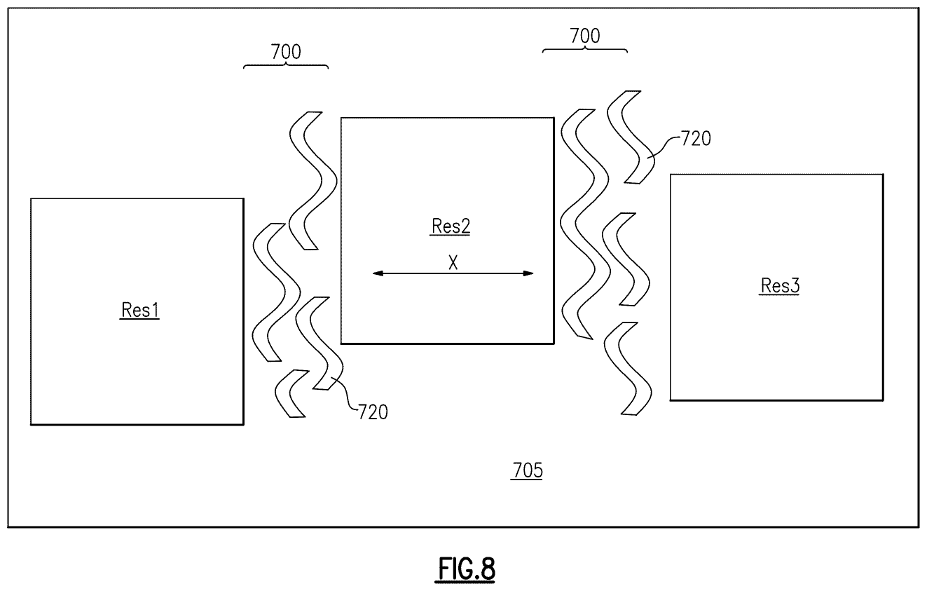

Examples of acoustic scattering structures are illustrated in FIG. 7, indicated generally at 700. FIG. 7 also includes blocks representing surface acoustic wave resonators Res1-Res3 that may have structures such as in any of the examples discussed above and that may or may not include reflector electrodes. The relative sizes and positioning of the surface acoustic wave resonators Res1-Res3 are exemplary only and not intended to be limiting. Electrical connections between the resonators Res1-Res3 are not shown for sake of clarity. The resonators Res1-Res3 include interdigital transducer electrodes disposed on a piezoelectric material layer of a substrate 705 which may be a multilayer piezoelectric substrate, for example, as illustrated in any of FIGS. 2, 3, or 4B-4E. Although only three resonators Res1-Res3 are shown, additional surface acoustic wave resonators may be present and together may form an acoustic wave device such as a radio frequency filter, for example, a ladder or lattice filter, a duplexer, multiplexer, or other form of acoustic wave device, for example, a duplexer as illustrated in FIG. 6.

Acoustic scattering structures 700 are disposed between Res1 and Res2 and between Res2 and Res3, or more specifically, between the interdigital transducer electrodes of Res1 and Res2 and between the interdigital transducer electrodes of Res2 and Res3. The acoustic scattering structures 700 are disposed on sides of the resonators Res1-Res3 in a direction parallel to a direction of propagation of main acoustic waves through the resonators, indicated in FIG. 7 by arrow X. The acoustic scattering structures 700 include one or more trenches 710 defined in the upper surface of the substrate 705, for example, in the layer of piezoelectric material upon which the interdigital transducer electrodes of the resonators Res1-Res3 are disposed. The trenches may be in the form of a plurality of joined line segments that are each angled relative to the direction of propagation of the main acoustic waves through the resonators. The line segments may be angled at any angle between 0° and 90° relative to a direction normal to the direction of propagation of the main acoustic waves through the resonators, for example, between 30° and 60° relative to a direction normal to the direction of propagation of the main acoustic waves through the resonators. In some examples, one or more of the trenches 710 may include only a single line segment. The trenches 710 may have overall lengths in the direction normal to the direction of propagation of the main acoustic waves through the resonators that are less that the widths of one or more of the resonators Res1-Res3 in the direction normal to the direction of propagation of the main acoustic waves through the resonators, or overall lengths greater than the width of one or more of the resonators Res1-Res3. The trenches 710 may all have the same lengths or one or more of the trenches 710 may have a different length than another one or more of the trenches 710. The widths of the trenches 710 may be the same for all trenches 710, or some of the trenches 710 may have different widths from others of the trenches. In some examples in which one of more of the resonators Res1-Res3 includes trenches 410 in its piezoelectric material layer 406 as in the resonator illustrated in FIGS. 4A-4E, the trenches 710 may have the same depth as the trenches 410 so that trenches 410 and 710 may be formed in the same manufacturing step. The trenches 410 and 710 may have the same or different widths.

In other embodiments, for example, as illustrated in FIG. 8, the acoustic scattering structures 700 may include one or more trenches 720 including one or more curved line segments defined in the upper surface of the substrate 705, for example, formed in the piezoelectric material layer upon which interdigital transducer electrodes of the resonators Res1-Res3 are disposed. In some embodiments, the acoustic scattering structures 700 may include both one or more trenches 710 with straight line segment(s) and one or more trenches 720 with curved line segment(s).

The concepts and embodiments of acoustic wave devices described herein are applicable to various types of devices, as would be understood by the skilled person. For example, aspects and embodiments disclosed herein may be applied to filters, duplexers, diplexers, or the like. The suppression of propagation of unwanted signals between acoustic wave devices in a circuit may lead to an improvement in the overall functioning of the circuit.

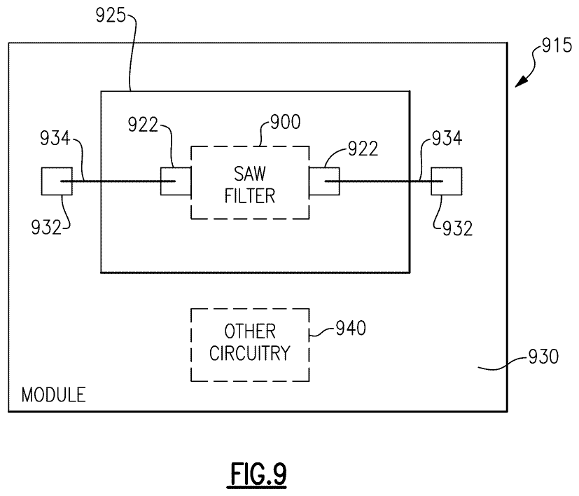

Embodiments of acoustic wave devices discussed herein can be implemented in a variety of packaged modules. Some examples of packaged modules will now be discussed in which any suitable principles and advantages of the acoustic wave devices discussed herein can be implemented. FIGS. 9, 10, and 11 are schematic block diagrams of illustrative packaged modules and devices according to certain embodiments.

As discussed above, aspects and embodiments of acoustic wave devices as disclosed herein can be used in radio frequency (RF) filters. In turn, an RF filter may be incorporated into and packaged as a module that may ultimately be used in an electronic device, such as a wireless communications device, for example. FIG. 9 is a block diagram illustrating one example of a module 915 including a SAW filter 900. The SAW filter 900 may be implemented on one or more die(s) 925 including one or more connection pads 922. For example, the SAW filter 900 may include a connection pad 922 that corresponds to an input contact for the SAW filter and another connection pad 922 that corresponds to an output contact for the SAW filter. The packaged module 915 includes a packaging substrate 930 that is configured to receive a plurality of components, including the die 925. A plurality of connection pads 932 can be disposed on the packaging substrate 930, and the various connection pads 922 of the SAW filter die 925 can be connected to the connection pads 932 on the packaging substrate 930 via electrical connectors 934, which can be solder bumps or wirebonds, for example, to allow for passing of various signals to and from the SAW filter 900. The module 915 may optionally further include other circuitry die 940, for example, one or more additional filter(s), amplifiers, pre-filters, modulators, demodulators, down converters, and the like, as would be known to one of skill in the art of semiconductor fabrication in view of the disclosure herein. In some embodiments, the module 915 can also include one or more packaging structures to, for example, provide protection and facilitate easier handling of the module 915. Such a packaging structure can include an overmold formed over the packaging substrate 930 and dimensioned to substantially encapsulate the various circuits and components thereon.

Various examples and embodiments of the SAW filter 900 can be used in a wide variety of electronic devices. For example, the SAW filter 900 can be used in an antenna duplexer, which itself can be incorporated into a variety of electronic devices, such as RF front-end modules and communication devices.

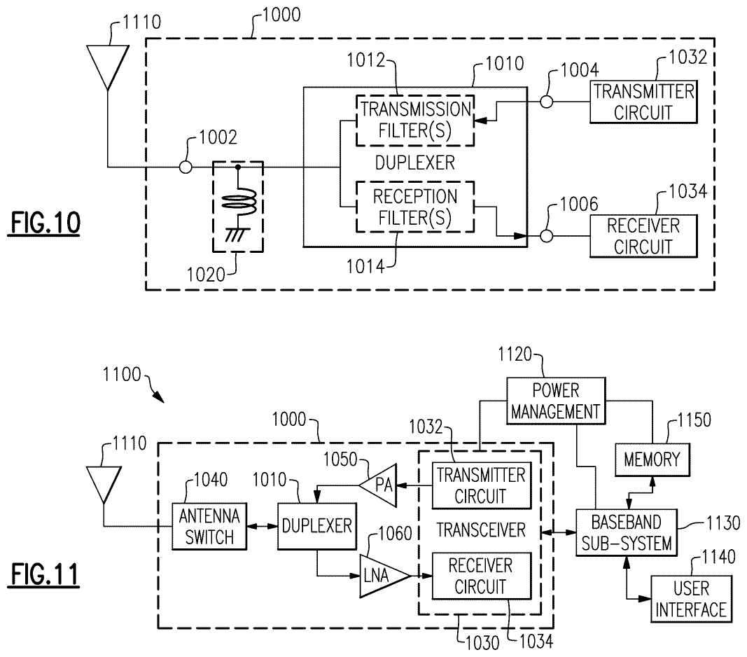

Referring to FIG. 10, there is illustrated a block diagram of one example of a front-end module 1000, which may be used in an electronic device such as a wireless communications device (e.g., a mobile phone) for example. The front-end module 1000 includes an antenna duplexer 1010 having a common node 1002, an input node 1004, and an output node 1006. An antenna 1110 is connected to the common node 1002.

The antenna duplexer 1010 may include one or more transmission filters 1012 connected between the input node 1004 and the common node 1002, and one or more reception filters 1014 connected between the common node 1002 and the output node 1006. The passband(s) of the transmission filter(s) are different from the passband(s) of the reception filters. Examples of the SAW filter 900 can be used to form the transmission filter(s) 1012 and/or the reception filter(s) 1014. An inductor or other matching component 1020 may be connected at the common node.

The front-end module 1000 further includes a transmitter circuit 1032 connected to the input node 1004 of the duplexer 1010 and a receiver circuit 1034 connected to the output node 1006 of the duplexer 1010. The transmitter circuit 1032 can generate signals for transmission via the antenna 1110, and the receiver circuit 1034 can receive and process signals received via the antenna 1110. In some embodiments, the receiver and transmitter circuits are implemented as separate components, as shown in FIG. 10, however, in other embodiments these components may be integrated into a common transceiver circuit or module. As will be appreciated by those skilled in the art, the front-end module 1000 may include other components that are not illustrated in FIG. 10 including, but not limited to, switches, electromagnetic couplers, amplifiers, processors, and the like.

FIG. 11 is a block diagram of one example of a wireless device 1100 including the antenna duplexer 1010 shown in FIG. 10. The wireless device 1100 can be a cellular phone, smart phone, tablet, modem, communication network or any other portable or non-portable device configured for voice or data communication. The wireless device 1100 can receive and transmit signals from the antenna 1110. The wireless device includes an embodiment of a front-end module 1000 similar to that discussed above with reference to FIG. 10. The front-end module 1000 includes the duplexer 1010, as discussed above. In the example shown in FIG. 11 the front-end module 1000 further includes an antenna switch 1040, which can be configured to switch between different frequency bands or modes, such as transmit and receive modes, for example. In the example illustrated in FIG. 11, the antenna switch 1040 is positioned between the duplexer 1010 and the antenna 1110; however, in other examples the duplexer 1010 can be positioned between the antenna switch 1040 and the antenna 1110. In other examples the antenna switch 1040 and the duplexer 1010 can be integrated into a single component.

The front-end module 1000 includes a transceiver 1030 that is configured to generate signals for transmission or to process received signals. The transceiver 1030 can include the transmitter circuit 1032, which can be connected to the input node 1004 of the duplexer 1010, and the receiver circuit 1034, which can be connected to the output node 1006 of the duplexer 1010, as shown in the example of FIG. 10.

Signals generated for transmission by the transmitter circuit 1032 are received by a power amplifier (PA) module 1050, which amplifies the generated signals from the transceiver 1030. The power amplifier module 1050 can include one or more power amplifiers. The power amplifier module 1050 can be used to amplify a wide variety of RF or other frequency-band transmission signals. For example, the power amplifier module 1050 can receive an enable signal that can be used to pulse the output of the power amplifier to aid in transmitting a wireless local area network (WLAN) signal or any other suitable pulsed signal. The power amplifier module 1050 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 1050 and associated components including switches and the like can be fabricated on gallium arsenide (GaAs) substrates using, for example, high-electron mobility transistors (pHEMT) or insulated-gate bipolar transistors (BiFET), or on a silicon substrate using complementary metal-oxide semiconductor (CMOS) field effect transistors.

Still referring to FIG. 11, the front-end module 1000 may further include a low noise amplifier (LNA) module 1060, which amplifies received signals from the antenna 1110 and provides the amplified signals to the receiver circuit 1034 of the transceiver 1030.

The wireless device 1100 of FIG. 11 further includes a power management sub-system 1120 that is connected to the transceiver 1030 and manages the power for the operation of the wireless device 1100. The power management sub-system 1120 can also control the operation of a baseband sub-system 1130 and various other components of the wireless device 1100. The power management sub-system 1120 can include, or can be connected to, a battery (not shown) that supplies power for the various components of the wireless device 1100. The power management sub-system 1120 can further include one or more processors or controllers that can control the transmission of signals, for example. In one embodiment, the baseband sub-system 1130 is connected to a user interface 1140 to facilitate various input and output of voice and/or data provided to and received from the user. The baseband sub-system 1130 can also be connected to memory 1150 that is configured to store data and/or instructions to facilitate the operation of the wireless device, and/or to provide storage of information for the user.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 500 MHz to 3 GHz.

Further examples of the electronic devices that aspects of this disclosure may be implemented include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A die comprising:
a first surface acoustic wave (SAW) resonator disposed on a surface of a substrate;
a second SAW resonator disposed on the surface of the substrate; and
an acoustic scattering structure disposed between the first SAW resonator and the second SAW resonator, the acoustic scattering structure including one or more trenches formed in the surface of the substrate.

2. The die of claim 1 wherein the one or more trenches have lengths and widths, the lengths of the one or more trenches being greater than the widths of the one or more trenches, the lengths of the one or more trenches extending in a direction normal to a direction of propagation of main acoustic waves through one or both of the first SAW resonator and the second SAW resonator.

3. The die of claim 2 wherein the one or more trenches include a first trench having a first length and a second trench having a second length different from the first length.

4. The die of claim 2 wherein the one or more trenches include a first trench having a first width and a second trench having a second width different from the first width.

5. The die of claim 2 wherein the one or more trenches include a first trench and a second trench, the first trench displaced from the second trench in the direction of propagation of the main acoustic waves through the one or both of the first SAW resonator and the second SAW resonator.

6. The die of claim 2 wherein the one or more trenches include a first trench and a second trench, the first trench displaced from the second trench in the direction normal to the direction of propagation of the main acoustic waves through the one or both of the first SAW resonator and the second SAW resonator.

7. The die of claim 2 wherein the one or more trenches each includes at least one linear section disposed at an angle relative to the direction normal to the direction of propagation of the main acoustic waves through the one or both of the first SAW resonator and the second SAW resonator in a plane defined by the surface of the substrate.

8. The die of claim 7 wherein the one or more trenches each includes multiple connected linear sections, at least one of the multiple connected linear sections disposed at an angle relative to at least one other of the multiple connected linear sections in the plane defined by the surface of the substrate.

9. The die of claim 1 wherein the one or more trenches each includes at least one curved section.

10. The die of claim 9 wherein the one or more trenches each includes multiple connected curved sections, at least one of the multiple connected curved sections having a different curvature than at least one other of the multiple connected curved sections.

11. The die of claim 1 wherein the substrate is a multilayer piezoelectric substrate including a layer of piezoelectric material having an upper surface upon which interdigital transducer electrodes of the first SAW resonator and the second SAW resonator are disposed.

12. The die of claim 11 wherein at least one of the first SAW resonator or the second SAW resonator includes a pair of interdigital transducer electrodes disposed on an upper surface of the layer of piezoelectric material, each interdigital transducer electrode including a bus bar and a plurality of electrode fingers extending from the bus bar towards an edge region of the interdigital transducer electrode at distal ends of the electrode fingers, and trench portions located in the upper surface of the layer of piezoelectric material, the trench portions overlapping with the edge regions of the interdigital transducer electrodes.

13. The die of claim 12 wherein the trench portions of the at least one of the first SAW resonator or the second SAW resonator and the one or more trenches of the acoustic scattering structure have same depths.

14. The die of claim 12 wherein the trench portions of the at least one of the first SAW resonator or the second SAW resonator and the one or more trenches of the acoustic scattering structure have same widths.

15. A radio frequency filter comprising:
interdigital transducer electrodes of a first surface acoustic wave (SAW) resonator disposed on a surface of a substrate;
interdigital transducer electrodes of a second SAW resonator disposed on the surface of the substrate; and
an acoustic scattering structure disposed between the interdigital transducer electrodes of the first SAW resonator and the interdigital transducer electrodes of the second SAW resonator, the acoustic scattering structure including one or more trenches formed in the surface of the substrate.

16. A duplexer including the radio frequency filter of claim 15.

17. The duplexer of claim 16 comprising a loop cancellation circuit including at least one of the first SAW resonator or the second SAW resonator, the at least one of the first SAW resonator or the second SAW resonator lacking reflector electrodes.

18. An electronics module comprising at least one radio frequency filter that includes:
interdigital transducer electrodes of a a first surface acoustic wave (SAW) resonator disposed on a surface of a substrate;
interdigital transducer electrodes of a second SAW resonator disposed on the surface of the substrate; and
an acoustic scattering structure disposed between the interdigital transducer electrodes of the first SAW resonator and the interdigital transducer electrodes of the second SAW resonator, the acoustic scattering structure including one or more trenches formed in the surface of the substrate.

19. The electronics module of claim 18 wherein the one or more trenches each includes multiple connected linear sections, at least one of the multiple connected linear sections disposed at an angle relative to at least one other of the multiple connected linear sections in the plane defined by the surface of the substrate.

20. The electronics module of claim 18 wherein the one or more trenches each includes multiple connected curved sections.
